(19) United States
(12) Patent Application Publication
(10) Pub. No.: US 2008/0158808 A1
(43) Pub. Date: Jul. 3, 2008

(54) Apparatus to protect shock-sensitive devices and methods of assembly

(75) Inventors: Manuel B. Camarena, Yorba Linda, CA (US); Jan Orlowski, Thousand Oaks, CA (US); Chi-Chi Lin, Alhambra, CA (US); Tom O. McGoldrick, Laguna Hills, CA (US)

Correspondence Address: SCHWEGMAN, LUNDBERG & WOESSNER, P.A., P.O. BOX 2938, MINNEAPOLIS, MN, 55402, US

(73) Assignee: Toshiba America Information Systems, Inc.

(21) Appl. No.: 11/648,201

(22) Filed: Dec. 29, 2006

(51) Int. Cl. H05K 7/14; H05K 5/00; H05K 7/00

(52) U.S. Cl. 361/685; 361/752

(57) ABSTRACT

At least one shock-sensitive device is mounted within an enclosure using a shock-absorbing element as an exclusive point of contact between the shock-sensitive device and the enclosure. The shock-sensitive device may comprise a disk drive and/or a printed circuit board. The enclosure may comprise an end cap having at least one mounting bracket or flange to receive the shock-absorbing element. The shock-sensitive device may comprise a mounting tab to receive a fastener, wherein one end of the fastener is received in the mounting tab, and wherein the other end of the fastener is received in the shock-absorbing element. The shock-absorbing element may comprise a resilient material such as rubber, silicone, urethane, or foam. In an embodiment, the end cap may include ventilation holes.

### TECHNICAL FIELD

The subject matter relates generally to shock-sensitive devices, and more particularly to apparatus to protect such devices, and to assembly methods related thereto.

### BACKGROUND INFORMATION

A “shock-sensitive device” as used herein is intended to include any product, the function of which may be adversely altered by exposure to mechanical shock or vibration. Examples of shock-sensitive devices include, but are not limited to, computers (e.g., hand-held device, laptop, desktop, server, router, Web appliance, etc.); wireless communications devices (e.g., cellular phone, cordless phone, pager, etc.); information storage devices (disk drives including magnetic and/or optical drives such as, but not limited to, CD (compact disc), DVD (digital versatile disc), HD DVD (high density digital versatile disc), Blu-ray™ optical disc technologies, flash memory, or the like); computer-related peripherals and components (e.g., printed circuit board, printer, scanner, monitor, sound card, network card, etc.); entertainment devices (e.g., personal music player, television, radio, stereo, tape and compact disc players, DVD player, video cassette recorder, camcorder, game device, digital camera, MP3 (Motion Picture Experts Group, Audio Layer 3) player, etc.); optical devices (camera, binoculars, etc.); measurement devices (thermometer, surveying instrument, GPS (Global Positioning System) equipment, range-finder, radar gun, radar detector, etc.); appliances (electric shaver, clock, timer, etc.); telematics and other vehicle navigation, communication, and entertainment devices; industrial equipment; military equipment; and other equipment containing shock-sensitive electronic, optical, mechanical, chemical, or biological components or material, or the like.

A disk drive (also referred to herein as a “hard drive”) is an information storage device. A disk drive may include one or more disks clamped to a rotating spindle, and at least one head for reading information representing data from and/or writing data to the surfaces of each disk. Disk drives are sensitive to mechanical shock. Mechanical shocks to disk drives may cause data to be incorrectly recorded or read, or to be lost, and they may cause irreparable damage to the disk drive components.

In the field of electronics there is competitive pressure among manufacturers to drive the performance of their equipment up while driving production and sales costs down and maintaining acceptable reliability, operation and performance. This is especially true for enclosing shock-sensitive devices, because the failure of packaging to address problems with mechanical shock, vibration, or user movement may lead to decreased reliability, operation and performance, unexpected device failure, and premature equipment replacement.

### BRIEF DESCRIPTION OF THE DRAWINGS

FIG. 1 is an exploded perspective representation of an enclosure to protect a shock-sensitive device, in accordance with an example embodiment of the subject matter;

FIG. 2 is an exploded side view of an end cap, a shock-absorbing element, a fastener, and a mounting tab, in accordance with an example embodiment of the subject matter;

FIG. 3 is a side view of an assembled end cap, a shock-absorbing element, a fastener, and a mounting tab, shown in cross-section taken through the center of the fastener, in accordance with an example embodiment of the subject matter; and

FIG. 4 is a flow diagram of several alternative methods of assembling an enclosure to protect a shock-sensitive device, in accordance with various example embodiments of the subject matter.

### DETAILED DESCRIPTION OF EXAMPLE EMBODIMENTS

In the following detailed description of example embodiments of the subject matter, reference is made to the accompanying drawings, which form a part hereof, and in which is shown by way of illustration specific example embodiments in which the subject matter may be practiced. These example embodiments are described in sufficient detail to enable those skilled in the art to practice the subject matter, and it is to be understood that other example embodiments may be utilized and that structural, mechanical, compositional, electrical, chemical, and procedural changes may be made without departing from the spirit and scope of the subject matter. The following detailed description is, therefore, not to be taken in a limiting sense, and the scope of the subject matter is defined only by the appended claims.

The following description includes terms, such as upper, lower, front, rear, first, second, etc. that are used for descriptive purposes only and are not to be construed as limiting. The example embodiments of an apparatus or article described herein can be manufactured, used, or shipped in a number of positions and orientations.

Reference will now be made to the drawings. In order to show the structures of various example embodiments most clearly, the drawings included herein are diagrammatic representations of enclosures for shock-sensitive devices and their associated structures. Thus, the actual appearance of the fabricated structures may appear different while still incorporating the basic structures of the illustrated example embodiments. Moreover, the drawings show only the structures that enable an understanding of the illustrated example embodiments. Additional structures known in the art have not been included to maintain the clarity of the drawings.

When housed in an enclosure, a shock-sensitive device may be damaged by mechanical shock or vibration transmitted through the enclosure and associated mounting hardware. When the device is one that is sensitive to shock, such as a hard disk drive, any movement, mechanical shock, or vibration transmitted to the device may cause immediate damage or failure, or it may have cumulative long term negative effects upon the reliability and/or operation of the device. Such reliability and operational problems may ultimately lead to device repair and/or replacement, as well as consumer dissatisfaction.

The inventive subject matter provides a solution to certain mechanical shock or vibration damage that may be associated with the packaging of shock-sensitive devices. In an example embodiment, means are provided for mounting one or more shock-sensitive devices within an enclosure using a shock-absorbing means or element as an exclusive point of contact between the shock-sensitive devices and the enclosure. In an example embodiment, a shock-sensitive device, such as a disk drive, may be coupled to a printed circuit board; however, in other embodiments a disk drive may be mounted within an enclosure without a printed circuit board. In another example embodiment, a shock-sensitive device may comprise only one or more printed circuit boards, or one or more printed circuit boards with other elements. The scope of embodiments of the inventive subject matter is not limited to any particular shock-sensitive device or to any particular combination of one or more shock-sensitive devices with other elements. The description hereinafter of an example embodiment of a printed circuit board mounted within an enclosure, and of a disk drive coupled to the printed circuit board, is not to be limiting, and it merely represents an example embodiment of many possible embodiments.

The enclosure may comprise at least one end cap having mounting brackets to receive the shock-absorbing elements. A shock-sensitive device may comprise at least one mounting tab to receive at least one fastener, wherein one end of the fastener is received in the mounting tab, and wherein the other end of the fastener is received in the shock-absorbing element. The shock-absorbing element may comprise a resilient material such as rubber, silicone, urethane, foam, or any compound with suitable shock-absorbent characteristics. In an example embodiment, the end cap may include ventilation holes. Various example embodiments are illustrated and described herein.

“Suitable”, as used herein, is intended to include having characteristics that are sufficient to produce the desired result(s). Suitability for the intended purpose can be determined by one of ordinary skill in the art using only routine experimentation.

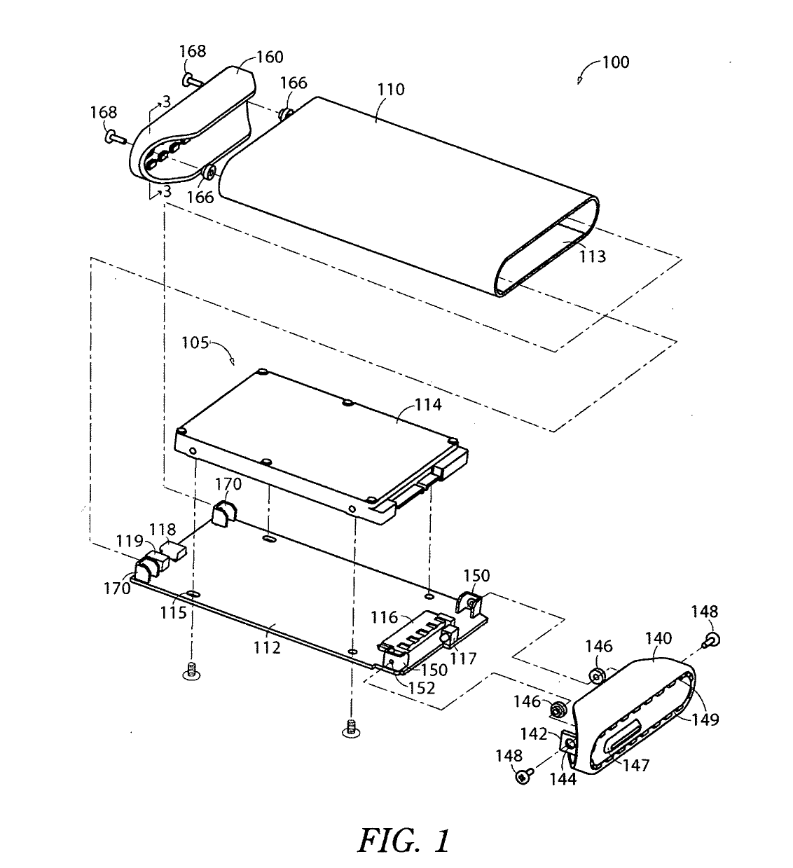

FIG. 1 is an exploded perspective representation of an enclosure 100 to protect a shock-sensitive device, in accordance with an example embodiment of the subject matter. The enclosure 100 may include a sleeve 110 to contain at least one shock-sensitive device 105. In an example embodiment, the shock-sensitive device 105 may be a disk drive 114. In an example embodiment, the shock-sensitive device 105 may be coupled to at least one printed circuit board 112. The enclosure 100 may further comprise a first end cap 140, a second end cap 160, and one or more shock-absorbing elements 146 and 166 to suspend (e.g., to exclusively suspend, in an example embodiment) the shock-sensitive device 105 within the sleeve 110 and between the end caps 140 and 160.

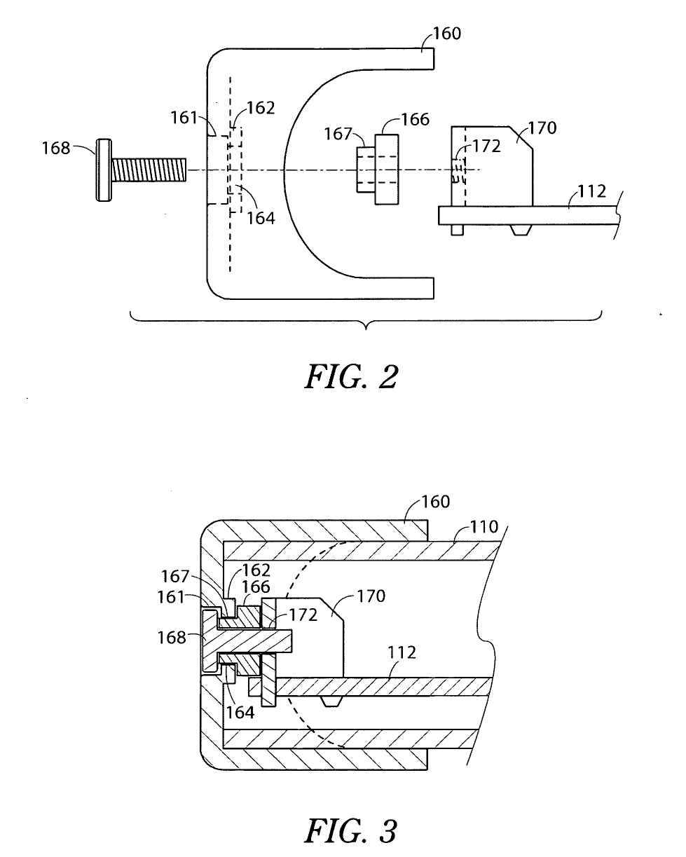

The one or more printed circuit boards 112 may include suitable device mounting holes 115 for mounting additional electronic devices, including any shock-sensitive electronic device, such as a disk drive 114. The printed circuit board 112 may include a device connector 116 to couple the disk drive 114 to the printed circuit board 112, a status lamp 117, connectors 118 and 119, and one or more mounting tabs 150 and 170 having corresponding mounting holes 152 and 172 (shown in FIG. 2) to receive fasteners 148 and 168, respectively.

In an example embodiment, mounting tabs 150 and 170 may comprise metal, such as steel; however, in other embodiments mounting tabs 150 and 170 may comprise any suitable material(s). In an example embodiment, a printed circuit board 112 may be coupled to one or more conductive springs (not shown) that make contact with the interior of sleeve 110 to reduce electromagnetic interference. In an example embodiment, the status lamp 117 may be coupled to the printed circuit board 112, and it may be visible through a suitable window or lens 147 on the first end cap 140.

In an example embodiment, connectors 118 and 119 on printed circuit board 112 may be used to connect power, signal, and/or other suitable electrical connections to a computer system. In an example embodiment, connectors 118 and 119 may comprise a connector conforming to the Universal Serial Bus (USB) standard, IEEE (Institute of Electrical and Electronics Engineers) 1394 bus standard, Serial Advanced Technology Attachment (SATA) standard, external Serial Advanced Technology Attachment (eSATA) standard, or other suitable standard; a power connector; or the like.

The sleeve 110 has interior dimensions appropriate to the length, width, and height of the shock-sensitive device 105 and any associated printed circuit board 112 that are to be enclosed. In an example embodiment, sleeve 110 may be longer in the dimension taken along the length between the two open ends than in the dimension taken along the width, as shown in FIG. 1. In an alternative example embodiment, the shock-sensitive device 105 and a printed circuit board 112 may be positioned within sleeve 110 in a manner different from that shown in FIG. 1, and the dimensions of sleeve 110 may be modified accordingly.

The sleeve 110 may comprise any suitable rigid or semi-rigid material. In an example embodiment, sleeve 110 may comprise aluminum having a wall thickness between one and two millimeters. In an example embodiment, sleeve 110 may comprise metal (such as steel, aluminum, copper, titanium, etc.), plastic (such as ABS (acrylonitrile butadiene styrene), acrylic, Lexan™, polymer, etc.), composite material (such as carbon fiber, Kevlar™, fiberglass, etc.), ceramic, wood, silicone, rubber, or the like.

In an example embodiment, the sleeve 110 may be at least partially lined with a non-conductive pad 113 to prevent electrical short circuits between the shock-sensitive device 105 and the interior of the sleeve 110. In an example embodiment, the non-conductive pad 113 may comprise a shock-absorbing material such as rubber, silicone, urethane, or foam.

The first end cap 140 and second end cap 160 fit over opposite ends of sleeve 110, and they may be coupled to the shock-sensitive device 105 exclusively through one or more shock-absorbing elements 146 and 166. The end caps 140 and 160 may comprise identical material, or they may each be of different material. In an example embodiment, one or both end caps 140 and 160 may comprise any suitable rigid or semi-rigid material of similar or identical types mentioned above regarding the sleeve. In an example embodiment, one or both end caps 140 and 160 may comprise ABS. In an example embodiment, one or both end caps 140 and 160 may comprise metal.

In an alternative example embodiment, instead of fitting over the ends of sleeve 110, one or both end caps 140 and 160 may fit within corresponding ends of sleeve 110, and they may have a flange or shoulder with outer dimensions approximately equal to the outer dimensions of sleeve 110.

In an example embodiment, one or both end caps 140 and 160 may comprise ventilation holes 149 arranged in a suitable manner to allow for cooling of the shock-sensitive device 105 and associated components within the enclosure 100. The ventilation holes may be fabricated in any suitable manner, such as by punching, drilling, molding, casting, or the like.

The first end cap 140 and the second end cap 160 may each comprise different suitable structures to allow coupling to a shock-sensitive device 105 by way of a shock-absorbing element 146. For example, the first end cap 140 may comprise one or more mounting brackets 142 that may be arranged substantially perpendicular to an outer surface (for example, the end) of the first end cap 140. The mounting bracket 142 may have a hole 144 to receive a shock-absorbing element 146.

The shock-absorbing element 146 may have a narrow portion (refer, for example, to narrow portion 167 of shock-absorbing element 166 in FIG. 2) to fit completely within and through the hole 144 of bracket 142. In an example embodiment, the end of the narrow portion may protrude a suitable distance from the surface of the mounting bracket 142 to better mechanically isolate the fastener 148 from the first end cap 140. In an alternative embodiment, one or both end caps 140 and 160 may not be present, and suitable mounting brackets, corresponding to mounting brackets 142, may be integrated within the interior of sleeve 110 or may originate from the printed circuit board 112.

In the embodiment shown in FIG. 1, it will be understood that once the shock-absorbing elements 146 are positioned between the mounting brackets 142, which may be provided on either end of the first end cap 140, and the mounting tabs 150 on either edge of printed circuit board 112, the printed circuit board 112 will be suspended from the first end cap 140 exclusively by the shock-absorbing elements 146. Therefore, the effect of any mechanical shock or vibration imparted to first end cap 140 upon printed circuit board 112 may be reduced. A shock-sensitive device 105 coupled to printed circuit board 112 will therefore also be relatively more insulated from shock.

The shock-absorbing elements 146 and 166 may comprise any suitable resilient material, such as, but not limited to, rubber, silicone, urethane, or foam. In an example embodiment, the shock-absorbing elements 146 and 166 comprise silicone having a hardness between 60 and 80 durometer (on the Shore “A” scale). In other example embodiments, other degrees of hardness may be used for the shock-absorbing elements. In an example embodiment, the shock-absorbing elements may have an outer diameter between four and seven millimeters. In an example embodiment the overall length of each shock-absorbing element may range from three to four millimeters. The specific geometry of the shock-absorbing element may be varied depending upon the corresponding geometry of the packaging elements.

The second end cap 160 may comprise one or more mounting flanges 162 (shown in FIGS. 2 and 3) that may be arranged substantially parallel to the outer surface of the second end cap 160. Accordingly (still referring to FIG. 1), the mounting tabs 170 on printed circuit board 112 may be arranged substantially perpendicular to mounting tabs 150, in order to receive shock-absorbing elements 166 and fasteners 168 from the outer surface of the second end cap 160. In an example embodiment, the shock-absorbing elements 166 and fasteners 168 are received within the mounting flanges 162 (FIGS. 2 and 3) in a manner substantially identical to that described above with reference to the first end cap 140. In an alternative example embodiment, the second end cap 160 may not be removable from the sleeve 110. The arrangement of the second end cap 160, shock-absorbing element 166, fastener 168, mounting tab 170, and printed circuit board 112 will now be described in greater detail with reference to FIGS. 2 and 3, below.

FIG. 2 is an exploded side view of a second end cap 160, a shock-absorbing element 166, a fastener 168, and a mounting tab 170, in accordance with an example embodiment of the subject matter. The shock-absorbing element 166 may have a narrow portion 167 to be received by a hole 164 suitably positioned within the wall of the second end cap 160. In an example embodiment, the region of the second end cap 160 surrounding where the hole 164 is placed may comprise a relatively thicker material. In another example embodiment, the region of the end cap surrounding where the hole 164 is placed may comprise a mounting flange 162, which may be approximately the same diameter as the outer diameter of the mounting surface or flange of the shock-absorbing element 166.

The hole 164 may have a countersunk region 161 on the exterior face of the second end cap 160. In an example embodiment, the countersunk region 161 may have a diameter 5%-10% larger than that of the head of fastener 168. In an example embodiment, fastener 168 may comprise a threaded fastener, such as a screw or bolt. In an alternative example embodiment, fastener 168 may comprise a rivet or other suitable non-threaded fastener.

The mounting tab 170 shown in FIG. 2 may be coupled to a printed circuit board 112 or other shock-sensitive device 105, such as any of the examples provided above. In an example embodiment, the mounting tab 170 may comprise metal, such as steel, or other suitable material. The mounting tab 170 may comprise a mounting hole 172 to receive the fastener 168. In an example embodiment, the mounting hole 172 may be threaded to receive a suitable screw or bolt. In an alternative example embodiment, the mounting hole 172 may hold a threaded rod to extend through the shock-absorbing element 166 and the outer surface of second end cap 160, and receive a threaded nut. The second end cap 160, mounted to a printed circuit board 112, is shown assembled in FIG. 3.

FIG. 3 is a side view of an assembled second end cap 160, a shock-absorbing element 166, a fastener 168, and a mounting tab 170, shown in cross-section taken through the center of the fastener, in accordance with an example embodiment of the subject matter. The view points in FIGS. 2 and 3 are identical, but in FIG. 3 a section has been made through the center of fastener 168 parallel to the plane of the page. All components shown are identical to those described in the detailed description of FIG. 2, above.

It will be understood that during assembly of enclosure 100, the second end cap 160 may not be coupled to a printed circuit board 112 until after the first end cap 140 has been coupled to the printed circuit board 112 and positioned on an end of the sleeve 110. In order to mount the second end cap 160 to the printed circuit board 112, a narrow portion 167 of shock-absorbing element 166 is received within the hole 164. The fastener 168 is then inserted through hole 164, through the hollow body of the shock-absorbing element 166, and is received by the mounting hole 172 in mounting tab 170.

Refer now to FIGS. 1-3. With a shock-absorbing element 146 positioned between a mounting bracket 142 on the end cap 140 and the mounting tab 150 on the printed circuit board 112, and with a shock-absorbing element 166 positioned between a flange 162 on the end cap 160 and the mounting tab 170 on the printed circuit board 112, the shock-absorbing elements 146 and 166 comprise exclusive points of contact between the printed circuit board 112 and the enclosure sleeve 110. Therefore, any mechanical shock or vibration affecting the exterior of the enclosure 100, whether occurring at the sleeve 110 or at one or both of the end caps 140 and 160, may be reduced by the shock-absorbing elements 146 and 166 before being transmitted to the mounting tabs 150 and 170, respectively, on printed circuit board 112.

In an example embodiment, the only physical connection between a shock-sensitive device 105 (for example, printed circuit board 112 and/or disk drive 114) and the enclosure 100 is through four shock-absorbing elements that are coupled only to the end caps (one pair of shock-absorbing elements 146 coupled to end cap 140, and one pair of shock-absorbing elements 166 coupled to end cap 160). There is no physical connection between the shock-sensitive device 105 (e.g. disk drive 114) and the sleeve 110, so if the enclosure 100 is bumped or dropped, the only shock transmission to the disk drive 114 is through the four shock-absorbing elements 146 and 166 from the end caps 140 and 160, respectively. Accordingly, the sizes of the shock-transmitting contacts are minimized, as opposed to an alternative package in which the shock-sensitive device 105 (e.g. disk drive 114) is coupled to the sleeve 110 through several square inches of contact. Thus, the amount of shock transfer is reduced.

In an example embodiment, shock-absorbing elements 146 and 166 may be identical. In an alternative embodiment, shock-absorbing element 146 may differ in size, shape, or composition from shock-absorbing element 166. In an example embodiment, a first shock-sensitive device 105 (e.g. printed circuit board 112) may be coupled to a second shock-sensitive device 105, such as a disk drive 114 (shown in FIG. 1). In an alternative example embodiment, mounting tabs, such as mounting tabs 150 and 170, may be coupled directly to a shock-sensitive device 105, such as disk drive 114. In other example embodiments, one or more printed circuit boards 112 may be coupled to any shock-sensitive device requiring isolation from mechanical shock or vibration.

The examples shown and described are not intended to be limiting. Alternative geometries are possible, depending upon the shock-sensitive device to be protected.

The assembly of an enclosure to protect a shock-sensitive device will now be described.

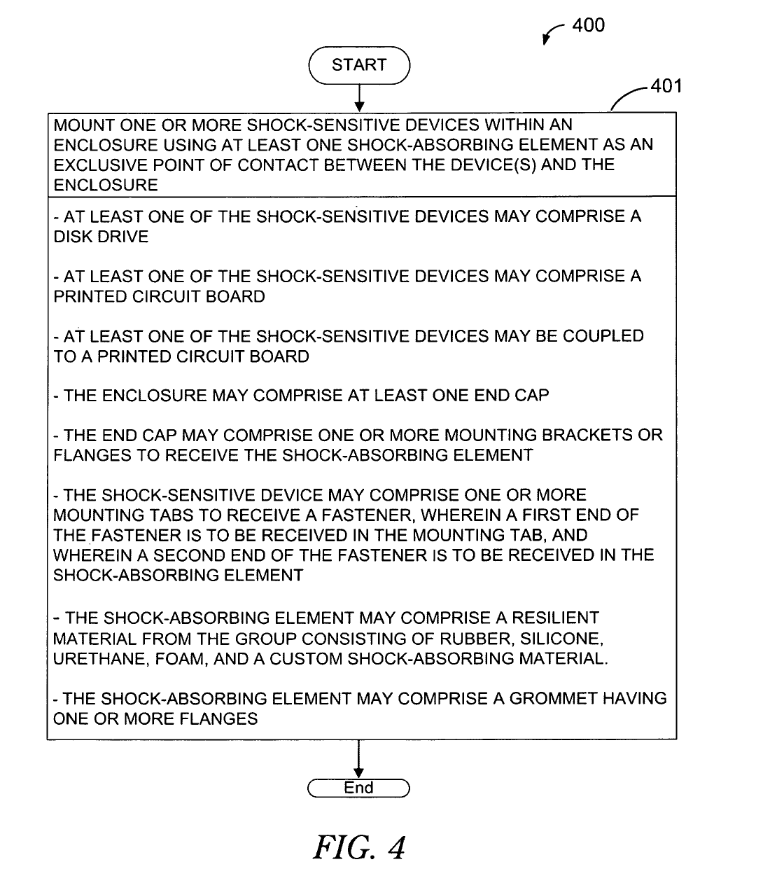

FIG. 4 is a flow diagram 400 of several alternative methods of assembling an enclosure to protect a shock-sensitive device, in accordance with various example embodiments of the subject matter.

In 401, one or more shock-sensitive devices are mounted within an enclosure using at least one shock-absorbing element as an exclusive point of contact between the device(s) and the enclosure. In an example embodiment, at least one of the shock-sensitive devices may comprise a disk drive. In an example embodiment, at least one of the shock-sensitive devices may comprise a printed circuit board. In an example embodiment, at least one of the one or more shock-sensitive devices may be coupled to at least one printed circuit board. In an example embodiment, the enclosure may comprise at least one end cap (as in end caps 140 and 160 in FIG. 1). In an example embodiment, the end cap may comprise one or more mounting brackets (as in 142 in FIG. 1) or flanges (as in 162 in FIGS. 2 and 3), to receive the shock-absorbing element (as in 146 and 166 in FIG. 1). In an example embodiment, the one or more mounting brackets may be located on the sleeve 110 or may be located on the printed circuit board 112. In an example embodiment, only one end cap or no end cap may be provided.

In an example embodiment, a shock-sensitive device may comprise one or more mounting tabs to receive a fastener (as in 168 in FIG. 3), wherein a first end of the fastener is received in the mounting tab, and wherein a second end of the fastener is received in the shock-absorbing element. In an example embodiment, the shock-absorbing element may comprise a resilient material from the group consisting of rubber, silicone, urethane, and foam. Alternatively, the shock-absorbing element may comprise a custom resilient and/or shock-absorbing material. In an example embodiment, the shock-absorbing element may comprise a grommet or tube having one or more flanges, as in 166 in FIG. 2. Grommet 166 may comprise dual flanges (not shown), for example.

The operations described above with respect to the methods illustrated in FIG. 4 may be performed in a different order from those described herein. Although the flow diagram of FIG. 4 shows an “End”, it may be performed continuously if desired.

FIGS. 1-3 are merely representational and are not drawn to scale. Certain proportions thereof may be exaggerated, while others may be minimized. FIGS. 1-4 are intended to illustrate various example embodiments of the subject matter that can be understood and appropriately carried out by those of ordinary skill in the art.

The inventive subject matter provides for enclosures, for apparatus, and for methods of assembly that may minimize mechanical shock or vibration damage problems associated with shock-sensitive devices.

Other example embodiments will be readily apparent to those of ordinary skill in the art after reading this disclosure.

Although specific example embodiments have been illustrated and described herein, it will be appreciated by those of ordinary skill in the art that any arrangement that is calculated to achieve the same purpose may be substituted for the specific example embodiment shown. This application is intended to cover any adaptations or variations of the subject matter. Therefore, it is manifestly intended that example embodiments of the subject matter be limited only by the claims and the equivalents thereof.

It is emphasized that the Abstract is provided to comply with 37 C.F.R. §1.72(b) requiring an Abstract that will allow the reader to ascertain the nature and gist of the technical disclosure. It is submitted with the understanding that it will not be used to interpret or limit the scope or meaning of the claims.

In the foregoing Detailed Description, various features are occasionally grouped together in a single embodiment for the purpose of streamlining the disclosure. This method of disclosure is not to be interpreted as reflecting an intention that the claimed example embodiments of the subject matter require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate example embodiment.

What is claimed is:

1. A method comprising:
mounting one or more shock-sensitive devices within an enclosure using at least one shock-absorbing element as an exclusive point of contact between the one or more shock-sensitive devices and the enclosure.

2. The method recited in claim 1, wherein at least one of the one or more shock-sensitive devices comprises a disk drive.

3. The method recited in claim 1, wherein at least one of the one or more shock-sensitive devices comprises a printed circuit board.

4. The method recited in claim 1, wherein the enclosure comprises at least one end cap, and wherein the at least one shock-absorbing element exclusively suspends the one or more shock-sensitive devices from the at least one end cap.

5. The method recited in claim 4, wherein the at least one end cap comprises one or more mounting flanges to receive the at least one shock-absorbing element.

6. The method recited in claim 1, wherein the one or more shock-sensitive devices comprises one or more mounting tabs to receive a fastener, wherein a first end of the fastener is received in the one or more mounting tabs, and wherein a second end of the fastener is received in the at least one shock-absorbing element.

7. The method recited in claim 1, wherein the at least one shock-absorbing element comprises a resilient material from the group consisting of rubber, silicone, urethane, foam, and a custom shock-absorbing material.

8. The method recited in claim 1, wherein the at least one shock-absorbing element comprises a grommet having one or more flanges.

9. An apparatus comprising:
an enclosure;
a shock-sensitive device to be mounted within the enclosure; and
one or more shock-absorbing elements exclusively suspending the device within the enclosure.

10. The apparatus recited in claim 9, wherein the device comprises a hard disk drive.

11. The apparatus recited in claim 9, wherein the device comprises a printed circuit board.

12. The apparatus recited in claim 9, wherein the one or more shock-absorbing elements comprises a resilient material.

13. The apparatus recited in claim 12, wherein the material comprises silicone.

14. The apparatus recited in claim 9, wherein the one or more shock-absorbing elements comprises a grommet.

15. The apparatus recited in claim 9, wherein the enclosure comprises a sleeve and at least one end cap, and wherein the one or more shock-absorbing elements exclusively suspends the device from the at least one end cap.

16. The apparatus recited in claim 15, wherein the one or more shock-absorbing elements comprises a silicone tube having a uniform inner diameter and two or more regions of unequal outer diameter.

17. The apparatus recited in claim 16, wherein the one or more shock-absorbing elements extend through one or more mounting tabs on the at least one end cap.

18. The apparatus recited in claim 15, wherein the at least one end cap comprises a plurality of ventilation holes.

19. The apparatus recited in claim 9, and further comprising:
one or more fasteners to secure the one or more shock-absorbing elements to the device.

20. The apparatus recited in claim 19, wherein the one or more fasteners make contact exclusively with the shock-sensitive device and the one or more shock-absorbing elements, respectively.

21. An apparatus comprising:
a shock-sensitive electronic device comprising two or more mounting tabs to receive a fastener;
an enclosure for the device comprising:
a sleeve;
two or more shock-absorbing elements;
a first end cap comprising one or more mounting brackets to receive at least one shock-absorbing element;
a second end cap comprising one or more mounting flanges to receive at least one shock-absorbing element; and
a fastener to exclusively suspend the device within the enclosure, wherein a first end of the fastener is secured in one of the mounting tabs, and wherein a second end of the fastener is secured in one of the shock-absorbing elements.

22. An apparatus comprising:
one or more shock-sensitive devices; and
means for mounting the one or more shock-sensitive devices within an enclosure using at least one shock-absorbing means as an exclusive point of contact between the one or more shock-sensitive devices and the enclosure.
